(19) United States
(12) Patent Application Publication
(10) Pub. No.: US 2026/0107584 A1
(43) Pub. Date: Apr. 16, 2026

(54) NANOPILLAR STRUCTURE OF IMAGE SENSOR DEVICE AND METHOD OF FORMING

(71) Applicant: Applied Materials, Inc., Santa Clara, CA (US)

(72) Inventors: Qintao Zhang, Mt. Kisco, NY (US); Yen Lin Leow, San Jose, CA (US); Manish Hemkar, Sunnyvale, CA (US); Zheng Yuan, Saratoga, CA (US)

(73) Assignee: Applied Materials, Inc., Santa Clara, CA (US)

(21) Appl. No.: 18/914,432

(22) Filed: Oct. 14, 2024

(51) Int. Cl. H01L 27/146

(52) U.S. Cl. CPC H10F 39/026; H10F 39/016; H10F 39/8053; H10F 39/811

(57) ABSTRACT

Disclosed herein are approaches for forming nanopillars of an image sensor. One method of forming an image sensor may include forming a first etch stop layer over a color filter, and forming a first trench fill material within a first plurality of trenches formed in a first spacer layer, wherein the first trench fill material extends to the first etch stop layer. The method may further include forming a second etch stop layer over the first trench fill material, and forming a second trench fill material within a second plurality of trenches of a second spacer layer, wherein the second spacer layer is formed over the second etch stop layer. The method may further include forming an opening through the first and second spacer layers, the opening exposing the first etch stop layer, and performing a wet etch through the opening to remove the first and second spacer layers.

### FIELD OF THE DISCLOSURE

The embodiments of the present disclosure relate to an image sensor and, in particular, to an image sensor having a nanopillar structure.

### BACKGROUND OF THE DISCLOSURE

Image sensors capture images by detecting light coming from the source. The color of incident light is captured by using a color filter. Color filters absorb unwanted wavelengths to filter and transmit only the desired color to the photodetector of the corresponding color channel, e.g., red, green, and blue. Although somewhat effective, this design is inefficient, capturing only a small fraction of light at the detector (e.g., less than 20-25% for a color filter array with a typical 2-by-2 pixel RGGB Bayer kernel), which makes low light imaging challenging and limits the practical size of image sensor pixels.

Recently, attempts have been made to use a meta lens to improve light utilization efficiency of image sensors. The meta lens separates colors of incident light by using diffraction or refraction characteristics of light that differ according to wavelengths, and adjusts the directionality of the incident light for each wavelength according to the refractive index and shape. To form high-aspect ratio pillars of the meta lens, a stack of trenched layers separated by one or more etch stop layers is often used. Each trenched layer may include low and high refractive index mediums. To improve optical characteristics of the device, a larger refractive index contrast between the low and high refractive index mediums is desirable.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method of forming an image sensor may include forming a first etch stop layer over a color filter, and forming a first trench fill material within a first plurality of trenches formed in a first spacer layer, wherein the first trench fill material extends to the first etch stop layer. The method may further include forming a second etch stop layer over the first trench fill material, and forming a second trench fill material within a second plurality of trenches of a second spacer layer, wherein the second spacer layer is formed over the second etch stop layer. The method may further include forming an opening through the first spacer layer and through the second spacer layer, the opening exposing the first etch stop layer, and performing a wet etch through the opening to remove the first spacer layer and the second spacer layer.

In another aspect, a method of forming a meta lens assembly may include forming a first etch stop layer over a spacer layer, wherein the spacer layer is formed over a color filter, and forming a first plurality of nanopillars by depositing a first trench fill material within a first plurality of trenches formed in a first spacer layer, wherein the first spacer layer is formed over the first etch stop layer. The method may further include forming a second plurality of nanopillars over the first plurality of nanopillars by depositing a second trench fill material within a second plurality of trenches formed in a second spacer layer, wherein the second spacer layer is formed atop a second etch stop layer, and forming an opening through the first spacer layer and through the second spacer layer, the opening exposing the first etch stop layer. The method may further include removing the first spacer layer and the second spacer layer, without removing the first plurality of nanopillars or the second plurality of nanopillars, by performing a wet etch through the opening.

In yet another aspect, an image sensor may include a first etch stop layer over a spacer layer, wherein the spacer layer is formed over a color filter, and a first plurality of nanopillars formed over the first etch stop layer, wherein a first set of adjacent nanopillars of the first plurality of nanopillars are separated from one another by a first airgap. The image sensor may further include a second plurality of nanopillars over the first plurality of nanopillars, wherein the second plurality of nanopillars are formed over a second etch stop layer, and wherein a second set of adjacent nanopillars of the second plurality of nanopillars are separated from one another by a second airgap. The image sensor may further include a capping layer formed over the second plurality of nanopillars.

### BRIEF DESCRIPTION OF THE DRAWINGS

The accompanying drawings illustrate exemplary approaches of the disclosure, including the practical application of the principles thereof, as follows:

FIG. 1 illustrates a cross-sectional side view of an image sensor including a base spacer layer and an etch stop layer formed over a color filter, according to embodiments of the present disclosure;

FIG. 2 illustrates a cross-sectional side view of the image sensor including a first spacer layer over the etch stop layer, according to embodiments of the present disclosure;

FIG. 3 illustrates a cross-sectional side view of the image sensor during patterning of a masking layer over the first spacer layer, according to embodiments of the present disclosure;

FIG. 4 illustrates a cross-sectional side view of the image sensor following formation of a plurality of trenches to form a first plurality of pillars in the first spacer layer, according to embodiments of the present disclosure;

FIG. 5 illustrates a cross-sectional side view of the image sensor following formation of a trench fill material within the plurality of trenches, according to embodiments of the present disclosure;

FIG. 6 illustrates a cross-sectional side view of the image sensor following formation of a second etch stop layer, according to embodiments of the present disclosure;

FIG. 7 illustrates a cross-sectional side view of the image sensor following formation of a second trench fill material within a second plurality of trenches of a second spacer layer, according to embodiments of the present disclosure;

FIG. 8 illustrates a cross-sectional side view of the image sensor after formation of an opening through the first and second spacer layers, according to embodiments of the present disclosure;

FIG. 9 illustrates a cross-sectional side view of the image sensor after removal of the first and second spacer layers, according to embodiments of the present disclosure;

FIG. 10 illustrates a cross-sectional side view of the image sensor after formation of a sealing layer, according to embodiments of the present disclosure; and

FIG. 11 illustrates a diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

Disclosed herein are techniques to form multiple, stacked layers of pillars formed in a spacer layer, wherein the pillars and spacer layer may be formed atop an etch stop later. One or more of the spacer layers may then be removed, leaving the pillars separated from one another by a low refractive index medium (e.g., air). The etch stop layer(s) supports the pillars following removal of the spacer layers. By using this approach, the optical properties of the image sensor may be improved due to the larger refractive index contrast between the low refractive index medium (e.g., air) and the relatively higher refractive index medium of the pillar material (e.g., titanium dioxide (TiO2), silicon dioxide (SiO2), tantalum oxide (Ta2O5), hafnium oxide (HfO2), aluminum oxide (Al2O3), or silicon nitride (SiN)).

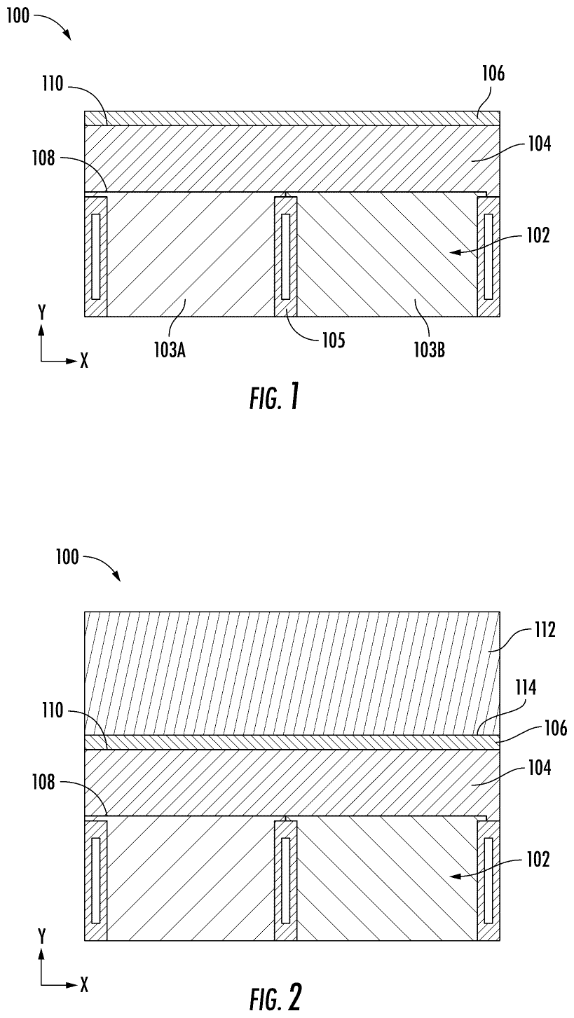

FIG. 1 illustrates an image sensor (hereinafter “sensor”) 100 at one stage of processing, according to embodiments of the present disclosure. In various embodiments, the sensor 100 may be a high-sensitivity complementary metal-oxide semiconductor (CMOS) image sensor (CIS), such as a meta lens image sensor, (also referred to as a meta lens assembly, meta optics, color splitting assembly, flat optics, nano-prism, or color routing assembly). Although the examples described herein operate over a spectrum including visible and near-infrared light, embodiments in accordance with the present disclosure can be configured for operation at wavelengths within virtually any electromagnetic spectral range, such as infrared, ultraviolet, multiple spectral ranges, and the like.

The sensor 100 may include a color filter 102, a base spacer layer 104 formed atop the color filter 102, and a first etch stop layer 106 formed atop the base spacer layer 104. The color filter 102 may include a plurality of pixels 103A and 103B, which are separated by a grid of low-refractive-index (LRI) components 105. The color filter 102 may be arranged as a two-dimensional (2-D) array structure having a plurality of rows and a plurality of columns.

Although not shown, the color filter 102 may be positioned over a plurality of photodiodes, which are formed in a substrate layer of the sensor 100. In some cases, the color filter 102 may not be present and, thus, the base spacer layer 104 may be formed directly atop the plurality of photodiodes.

In some embodiments, the base spacer layer 104 may be an oxide, e.g., silicon dioxide (SiO2) or silicon carbon nitride (SiCN), which is deposited over an upper surface 108 of the color filter 102 and then recessed (e.g., planarized) to a desired thickness. The etch stop layer 106, which may be a nitride, e.g., silicon nitride (SiN), is then deposited directly atop an upper surface 110 of the recessed base spacer layer 104. The first etch stop layer 106 may be formed to a non-limiting thickness of approximately 20 nm-50 nm.

As shown in FIG. 2, one or more first spacer layers 112 may be formed over the first etch stop layer 106 and then recessed. Although non-limiting, the first spacer layer 112 may be a layer of SiO2 or SiCN, which is deposited directly atop an upper surface 114 of the etch stop layer 106 and then recessed (e.g., planarized) to a desired thickness.

As shown in FIG. 3, a first masking layer 116 may be formed over the first spacer layer 112. In some embodiments, the first masking layer 116 may be a photoresist, which is deposited directly atop an upper surface 120 of the first spacer layer 112 and then patterned using an electromagnetic radiation 122, for e.g., ultraviolet light (UV), deep ultraviolet light (DUV), extreme ultraviolet light (EUV), or-ray. This exposure introduces a latent image or pattern on the photoresist with different areas of solubility, as desired.

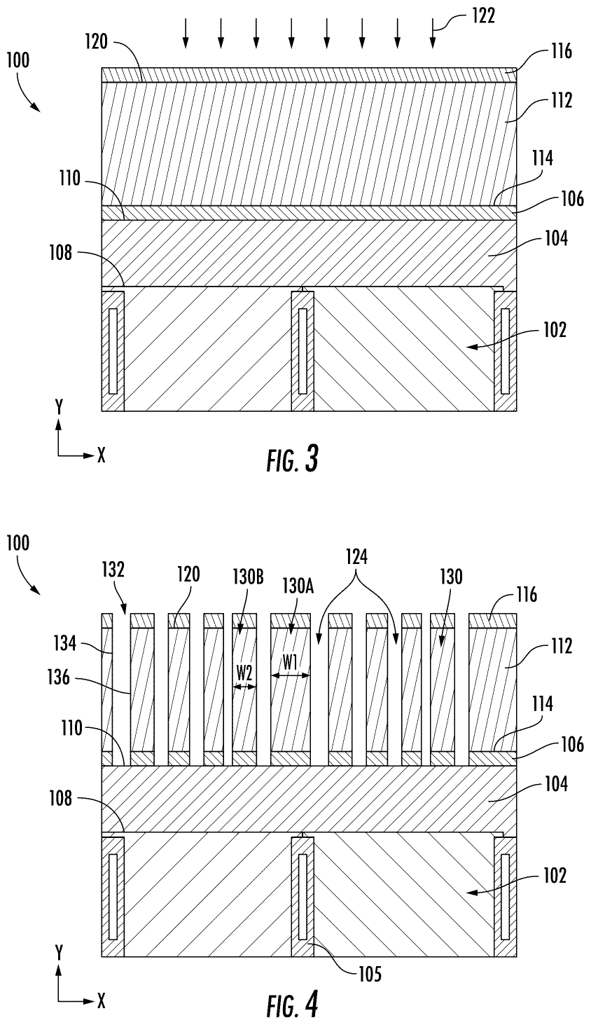

As shown in FIG. 4, a first plurality of trenches 124 may then be formed through openings 132 of the first masking layer 116 and through the first spacer layer 112 to produce a first plurality of support elements 130. In some embodiments, the trenches 124 may be formed using a vertical etch process, which continues to the upper surface 114 of the first etch stop layer 106. For example, an etchant may be used to generate a high etch selectivity of the first spacer layer 112 to the first etch stop layer 106. Each of the first plurality of support elements 130 may be defined by a first sidewall 134, a second sidewall 136, and the upper surface 114 of the etch stop layer 106. Although non-limiting, the first sidewall 134 and the second sidewall 136 may be generally parallel to one another.

The first plurality of support elements 130 may have a same or different horizontal width (e.g., in the x-direction), and the plurality of trenches 124 may have a same or different horizontal width. For example, in the embodiment shown, a first support element 130A may have a first width, W1, and a second support element 130B may have a second width, W2, wherein W1 is greater than W2. The size and width of each of support element 130 may be a function of the desired routing of light having certain wavelengths. In some embodiments, the first support element 130A may be generally aligned above the LRI component 105 of the color filter 102 so as to minimize interference with routing of light.

As shown in FIG. 5, the first masking layer 116 may be removed from the upper surface 120 of the first spacer layer 112, and a first trench fill material 140 may be formed within each of the plurality of trenches 124 to form a first plurality of pillars or nanopillars 135. The first trench fill material 140 may extend to the upper surface 110 of the base spacer layer 104. In some embodiments, the first masking layer 116 may be removed using a photoresist plasma ashing process in which oxygen and a fluorocarbon, such as CF₄ or C₂F₆, are supplied to the sensor 100 to strip the photoresist layers of the first masking layer 116.

In some embodiments, the first trench fill material 140 may be Si3N4, (SiO2), Ta2O5, HfO2, Al2O3 or TiO2. In other embodiments, the first trench fill material 140 may include zinc sulfide (ZnS), gallium nitride (GaN), zinc selenide (ZnSe), or a combination thereof. The first trench fill material 140 may include materials having a relatively higher refractive index (RI), e.g., greater than two (2).

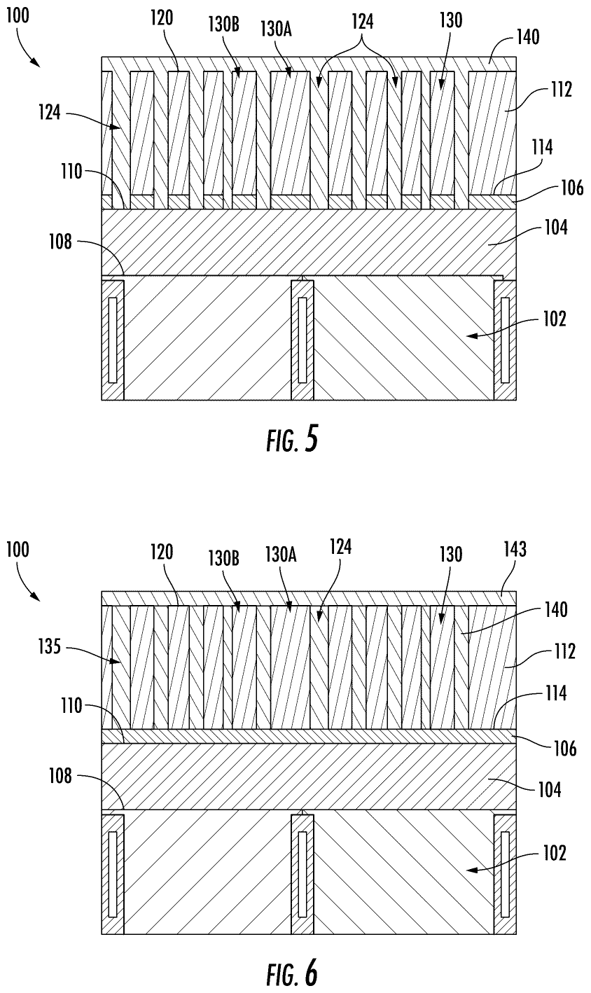

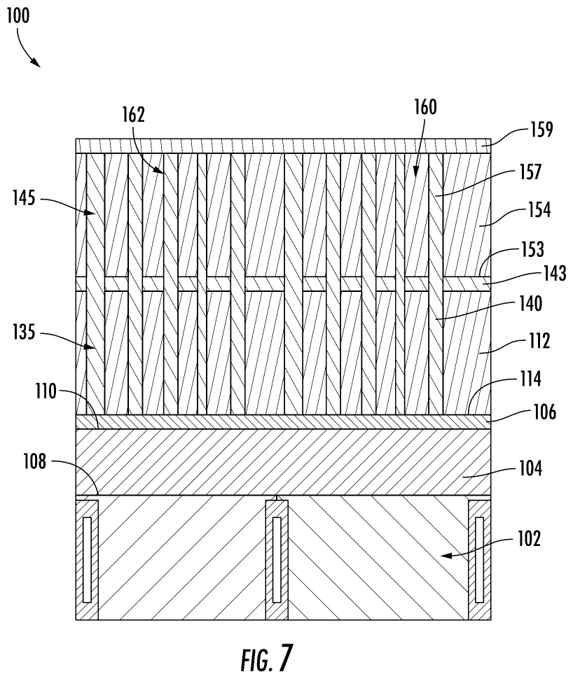

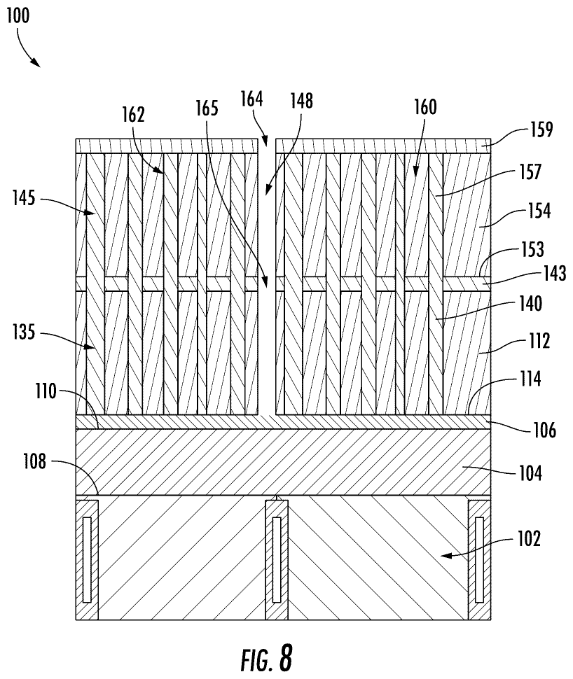

The first trench fill material 140 may also be formed along the upper surface 120 of the first spacer layer 112 and then planarized or otherwise removed, resulting in the sensor 100 shown in FIG. 6. The first trench fill material 140 may extend to the upper surface 114 of the etch stop layer 106. A second etch stop layer 143 may then be formed over the first trench fill material 140 and over the upper surface 120 of the first spacer layer 112. In some embodiments, the second etch stop layer 143 may be a nitride, e.g., silicon nitride (SiN).

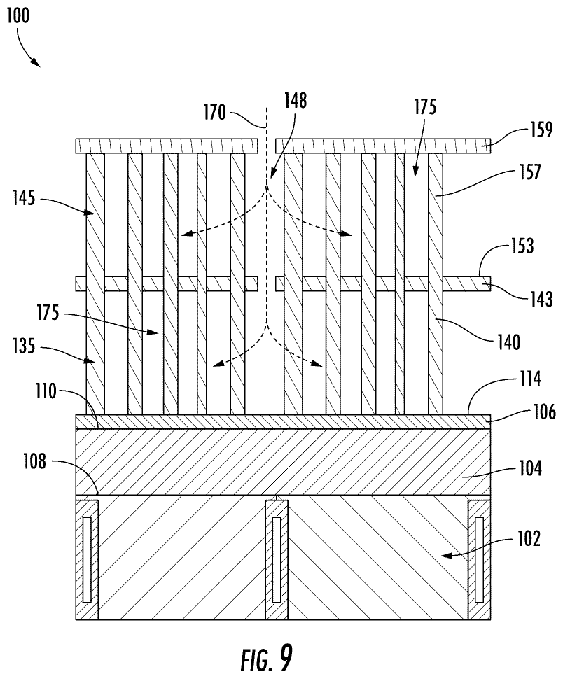

As shown in FIG. 7, a second plurality of nanopillars 145 may be formed in a second spacer layer 154, which is formed over the second etch stop layer 143. The process used to form the first plurality of nanopillars 135 may be repeated to form the second plurality of nanopillars 145 and a second plurality of support elements 160. For example, a plurality of trenches 162 may be formed through the second spacer layer 154, which may be SiO2 or SiCN, to define the second plurality of support elements 160, and a second trench fill material 157 may be formed within each of the plurality of trenches 162 to form the second plurality of nanopillars 145. In some embodiments, the second trench fill material 157 may be TiO2, SiO2, Ta2O5, HfO2, Al2O3 or SiN. A capping layer 159 may be formed over the second plurality of support elements 160 and the second plurality of nanopillars 145.

In this embodiment, the second trench fill material 157 may extend through the second etch stop layer 143 until the second trench fill material 157 connects with the first trench fill material 140 of the first plurality of nanopillars 135. For example, a first etchant may be used to generate a high etch selectivity of the second spacer layer 154 to the second etch stop layer 143 (e.g., SiO2 of the second spacer layer 154 is etched faster than SiN of the second etch stop layer 143) to form the plurality of trenches 162. After the first etchant stops on an upper surface 153 of the second etch stop layer 143, a second etchant may be used to generate a high etch selectivity of the second etch stop layer 143 relative to the first trench fill material 140 (e.g., SiN of the second etch stop layer 143 is etched faster than TiO2 of the first trench fill material 140).

As shown in FIG. 8, one or more of the second plurality of support elements 160 may be etched to form an opening 148 through the first spacer layer 112 and the second spacer layer 154. More specifically, the opening 148 may extend to the upper surface 114 of the first etch stop layer 106 by forming a first slit 164 through the capping layer 159 followed by a second slit 165 through the second etch stop layer 143. One or more etchants may be used to remove the various materials of the capping layer 159, the second spacer layer 154, the second etch stop layer 143, and the first spacer layer 112.

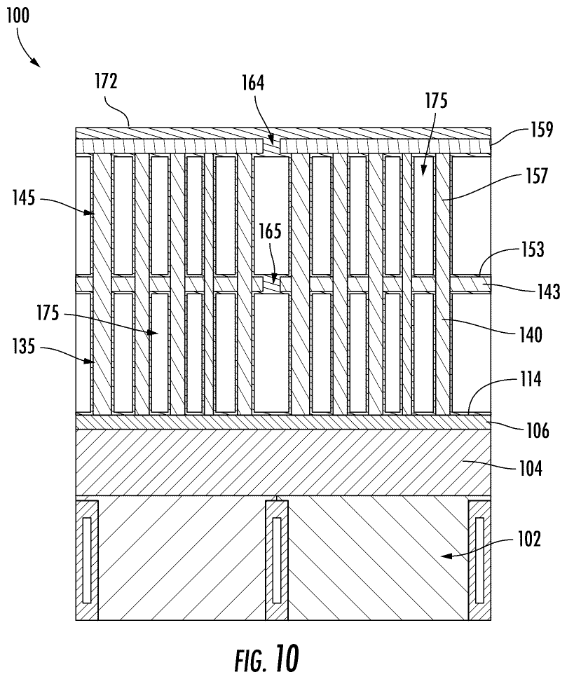

As shown in FIG. 9, the first and second spacer layers 112, 154 may be removed by performing a wet etch 170 through the opening 148. In general, the wet etch 170 is selective to the first and second etch stop layers 106, 143 and does not remove material from the first plurality of nanopillars 135 or the second plurality of nanopillars 145. As a result, a plurality of voids or airgaps 175 are formed around/between the first plurality of nanopillars 135 and the second plurality of nanopillars 145. Leaving the first and second plurality of nanopillars 135, 145 separated from one another by a low refractive index medium (e.g., air) maximizes the refractive index contrast between the high index material (e.g., TiO2) of the first and second plurality of nanopillars 135, 145 and the low index medium.

In some embodiments, the wet etch 170 may include delivering a solution into the opening 148, wherein the solution may contain hydrofluoric acid (HF), phosphoric acid (H₃PO₄), one or more hydroxides (e.g., sodium hydroxide (NaOH), potassium hydroxide (KOH), lithium hydroxide (LiOH), ammonium hydroxide (NH₄OH)), or salts thereof. A dilute hydrofluoric acid (DHF) solution having a concentration from about 50:1 to about 1,000:1 (in water) can be used in some embodiments. However, the etching chemistry may vary in alternative embodiments, and can be selected based on the composition of the first and second spacer layers 112, 154 to be removed.

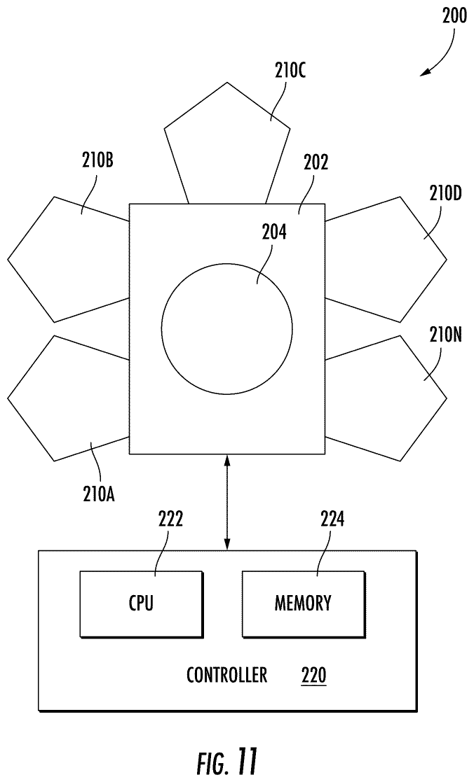

As shown in FIG. 10, a sealing layer 172 may then be formed over the sensor 100, including along exposed surfaces of the first plurality of nanopillars 135 and the second plurality of nanopillars 145. The sealing layer 172 may be formed by atomic layer deposition (ALD), and may seal the first slit 164 of the capping layer 159 and the second slit 165 of the second etch stop layer 143. In some embodiments, the sealing layer 172 may be a nitride, e.g., SiN. However, another material may be used for the sealing layer 172 in alternative embodiments. The sealing layer 172 may have a lower refractive index than the first plurality of nanopillars 135 and the second plurality of nanopillars 145.

At this stage of processing, the sensor 100 shown in FIG. 10 may be a CIS having the first etch stop layer 106 over the base spacer layer 104, wherein the base spacer layer 104 is formed over the color filter 102. The first plurality of nanopillars 135 are formed over the first etch stop layer 106 wherein a first set (i.e., two or more) of adjacent nanopillars of the first plurality of nanopillars 135 are separated from one another by a first airgap 175. The second plurality of nanopillars 145 are formed over the first plurality of nanopillars 135, wherein the second plurality of nanopillars 145 is separated from the first plurality of nanopillars 135 by the second etch stop layer 143, and wherein a second set of adjacent nanopillars of the second plurality of nanopillars 145 are separated from one another by a second airgap 175. The capping layer 159 may be formed over the second plurality of nanopillars 145. In some embodiments, the sealing layer 172 may be formed along exposed surfaces of the first plurality of nanopillars 135 and the second plurality of nanopillars 145, and may seal the first slit 164 of the capping layer 159 and the second slit 165 of the second etch stop layer 143.

FIG. 11 shows a schematic of an example apparatus/system 200 according to implementations of the disclosure. In some implementations, the system 200 may be a cluster tool operable to perform processes necessary to form the sensor 100 described herein. Examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

As shown, the system 200 may include at least one central transfer station/chamber 202 and one or more robots 204 within the transfer station/chamber 202, wherein the robot 204 is operable to move a robot blade and a wafer to and from each of a plurality of processing chambers 210A-210N connected with, or positioned adjacent to, the transfer station/chamber 202. In some implementations, the processing chambers 210A-210N may support ion implantation, material deposition, material etching, thermal processing, and others. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some implementations, processing chamber 210A may be a deposition chamber operable to deposit one or more layers or features of the sensor 100. For example, the processing chamber 210A may include a material deposition tool operable to form the first spacer layer 112 over the first etch stop layer 106, and to form the second spacer layer 154 over the second etch stop layer 143. The material deposition tool may be further operable to form the first trench fill material 140 within the trenches of the first spacer layer 112, and the second trench fill material 157 within the trenches of the second spacer layer 154. The material deposition tool may be still further operable to form the sealing layer 172. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition. The deposition chamber may further be an epitaxial growth deposition chamber.

In some implementations, processing chamber 210B may be an etch chamber operable to form one or more trenches through the body of the sensor 100. For example, the processing chamber 210B may include an ion etching tool operable to form the trenches in the first and second spacer layers 112, 154 and to form the opening 148. In some implementations, processing chamber 210B may be used for wet and/or dry etch processes. For example, a wet etch may be used to remove the first and second spacer layers 112, 154 to form the airgaps 175 between the first and second nanopillars 135, 145. In some implementations, the processing chamber 210B may be further operable to planarize one or more layers of the sensor 100, e.g., to partially remove the first trench fill material 140 and the second trench fill material 157.

In some implementations, processing chamber 210C may be operable to perform an ion implant to the sensor 100, while processing chamber 210D may be operable to perform one or more thermal processes.

A system controller 220 is in communication with the robot 204, the transfer station/chamber 202, and the plurality of processing chambers 210A-210N. The system controller 220 can be any suitable component that can control the processing chambers 210A-210N and robot(s) 204, as well as the processes occurring within the process chambers 210A-210N. For example, the system controller 220 can be a computer including a central processor 222, memory 224, suitable circuits/logic/instructions, and storage.

Processes or instructions may generally be stored in the memory 224 of the system controller 220 as a software routine that, when executed by the processor 222, causes the processing chambers 210A-210N to perform processes of the present disclosure. The software routine may also be stored and/or executed by a second processor (not shown) that is remotely located from the hardware being controlled by the processor 222. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 222, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one implementation” of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over”or “directly atop”another element, no intervening elements are present.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of forming an image sensor, the method comprising:
forming a first etch stop layer over a color filter;
forming first nanopillars in a first spacer layer, wherein the first nanopillars extend to the first etch stop layer;
forming a second etch stop layer over the first nanopillars;
forming second nanopillars in a second spacer layer, wherein the second spacer layer is formed over the second etch stop layer;
forming at least one opening through the first spacer layer and through the second spacer layer; and
performing an etch through the at least one opening to remove the first spacer layer and the second spacer layer.

2. The method of claim 1, further comprising forming a capping layer over the second nanopillars and over the second spacer layer.

3. The method of claim 2, wherein forming the at least one opening further comprises forming a first slit through the capping layer and forming a second slit through the second etch stop layer, wherein the at least one opening extends to the first etch stop layer.

4. The method of claim 3, further comprising sealing the first slit and the second slit with a sealing layer.

5. The method of claim 1, further comprising patterning a masking layer over the first spacer layer, wherein a first plurality of trenches are formed through openings of the masking layer.

6. The method of claim 1, wherein the first spacer layer has a first refractive index, wherein the first nanopillars have a second refractive index, and wherein the first refractive index is less than the second refractive index.

7. The method of claim 1, wherein the second spacer layer has a first refractive index, wherein the second nanopillars have a second refractive index, and wherein the first refractive index is less than the second refractive index.

8. The method of claim 1, wherein the first spacer layer and the second spacer layer are a same material, and wherein the first nanopillars and the second nanopillars are a same material.

9. The method of claim 1, further comprising:
depositing a first trench fill material within a first plurality of trenches of the first spacer layer to form the first nanopillars, wherein the first trench fill material comprises at least one of the following: silicon nitride, silicon dioxide, tantalum oxide, hafnium oxide, aluminum oxide, and titanium dioxide; and
depositing a second trench fill material within a second plurality of trenches of the second spacer layer to form the second nanopillars, wherein the second trench fill material comprises at least one of the following: silicon nitride, silicon dioxide, tantalum oxide, hafnium oxide, aluminum oxide, and titanium dioxide.

10. A method of forming a meta lens assembly, the method comprising:
forming a first etch stop layer over a base spacer layer, wherein the base spacer layer is formed over a color filter;
forming a first plurality of nanopillars by depositing a first trench fill material within a first plurality of trenches formed in a first spacer layer, wherein the first spacer layer is formed over the first etch stop layer;
forming a second plurality of nanopillars over the first plurality of nanopillars by depositing a second trench fill material within a second plurality of trenches formed in a second spacer layer, wherein the second spacer layer is formed atop a second etch stop layer;
forming at least one opening through the second etch stop layer and through the second spacer layer; and
removing the first spacer layer and the second spacer layer by performing a wet etch through the opening, wherein the first plurality of nanopillars or the second plurality of nanopillars remain following the wet etch.

11. The method of claim 10, wherein forming the at least one opening further comprises forming a first slit through a capping layer deposited over the second plurality of nanopillars, and forming a second slit through the second etch stop layer.

12. The method of claim 11, further comprising sealing the first slit and the second slit with a sealing layer after performing the wet etch.

13. The method of claim 10, further comprising patterning a masking layer over the first spacer layer, wherein the first plurality of trenches are formed through openings of the masking layer.

14. The method of claim 10, wherein the first spacer layer has a first refractive index, wherein the first trench fill material has a second refractive index, and wherein the first refractive index is less than the second refractive index.

15. The method of claim 10, wherein the first spacer layer and the second spacer layer are a same material, and wherein the first trench fill material and the second trench fill material are a same material.

16. The method of claim 10, wherein depositing the first trench fill material in the first plurality of trenches comprises depositing one of the following: silicon nitride, silicon dioxide, tantalum oxide, hafnium oxide, aluminum oxide, and titanium dioxide, and wherein depositing the second trench fill material in the second plurality of trenches comprises depositing one of the following: silicon nitride, silicon dioxide, tantalum oxide, hafnium oxide, aluminum oxide, and titanium dioxide.

17. An image sensor, comprising:
a first etch stop layer over a base spacer layer, wherein the base spacer layer is formed over a color filter;
a first plurality of nanopillars formed over the first etch stop layer, wherein a first set of adjacent nanopillars of the first plurality of nanopillars are separated from one another by a first airgap;
a second plurality of nanopillars over the first plurality of nanopillars, wherein the second plurality of nanopillars are formed over a second etch stop layer, and wherein a second set of adjacent nanopillars of the second plurality of nanopillars are separated from one another by a second airgap; and
a capping layer formed over the second plurality of nanopillars.

18. The image sensor of claim 17, further comprising a sealing layer formed along one or more exposed surfaces of the first plurality of nanopillars and the second plurality of nanopillars.

19. The image sensor of claim 17, wherein the first plurality of nanopillars and the second plurality of nanopillars are a same material.

20. The image sensor of claim 17, wherein the first plurality of nanopillars and the second plurality of nanopillars are one of: silicon nitride, silicon dioxide, tantalum oxide, hafnium oxide, aluminum oxide, and titanium dioxide.
